(19) United States
(12) Patent Application Publication
(10) Pub. No.: US 2026/0239966 A1
(43) Pub. Date: Aug. 13, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ping-Jung Wu, Hsinchu (TW); Chia-Hao Hsu, Hsinchu (TW); Tsang-Jiuh Wu, Hsinchu (TW); Yung-Chi Lin, New Taipei City (TW); Jyu-Horng Shieh, Hsin-Chu (TW)

(73) Assignee: Taiwan Semiconductor Manufacturing Company, Ltd., Hsinchu (TW)

(21) Appl. No.: 19/047,626

(22) Filed: Feb. 7, 2025

(51) Int. Cl. H01L 23/373; H01L 21/48; H01L 23/00; H01L 23/31; H01L 23/498

(52) U.S. Cl. CPC H10W 40/255; H10W 40/037; H10W 40/254; H10W 70/60; H10W 74/114; H10W 90/736

(57) ABSTRACT

A semiconductor device includes a heat dissipation substrate. The heat dissipation substrate includes a substrate, a first material layer, a second material layer, a eutectic metal layer and a bonding layer. The first material layer is disposed on the first substrate and includes a first component of a eutectic metal. The second material layer is disposed on the first material layer and includes a second component of the eutectic metal. The eutectic metal layer is disposed between the first material layer and the second material layer and includes the eutectic metal. The bonding layer is disposed on the second material layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are schematic cross-sectional views of various stages in a method of manufacturing a semiconductor device according to some embodiments.

FIG. 2 is a schematic cross-sectional view of a semiconductor device according to some embodiments.

FIG. 3 is a schematic cross-sectional view of a semiconductor device according to some embodiments.

FIG. 4 is a schematic cross-sectional view of a semiconductor device according to some embodiments.

FIG. 5A to FIG. 5E are schematic cross-sectional views of various stages in a method of forming a semiconductor device according to some embodiments.

FIG. 6 is a schematic cross-sectional view of a semiconductor device according to some embodiments.

FIG. 7 illustrates a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or features relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

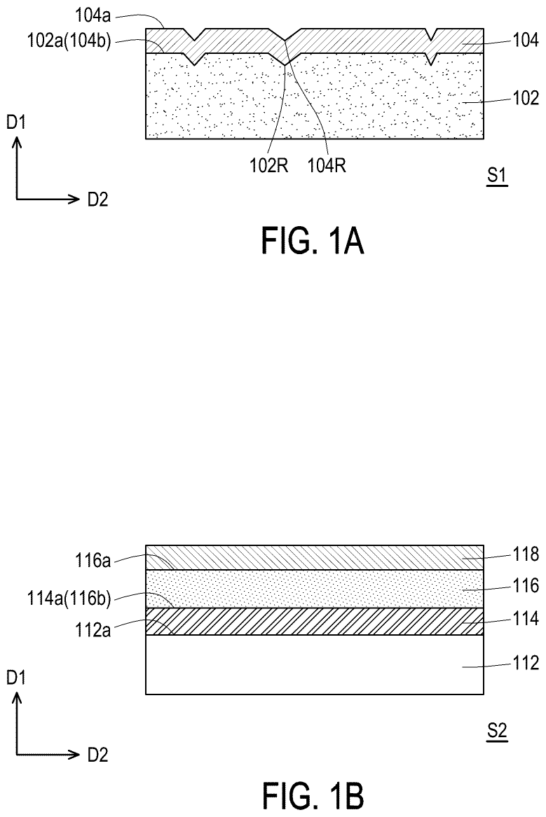

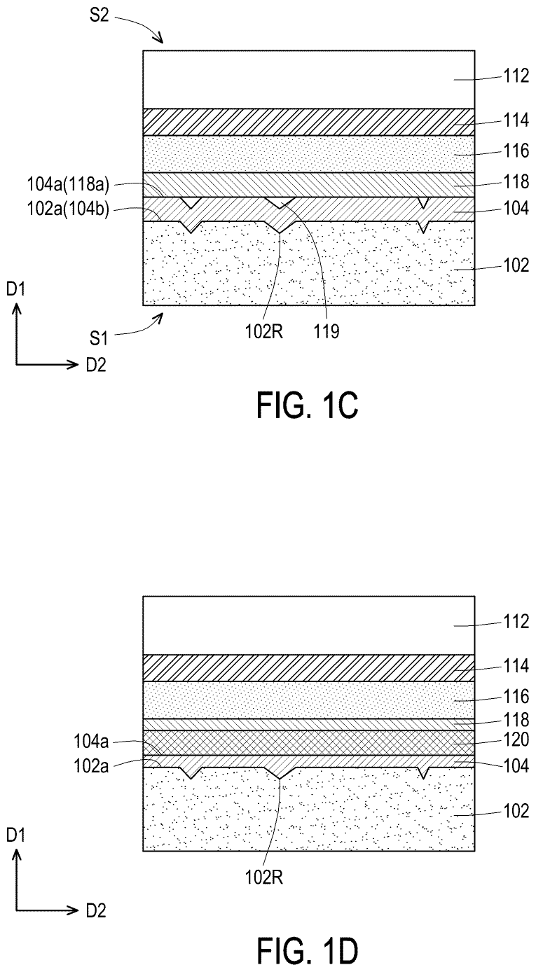

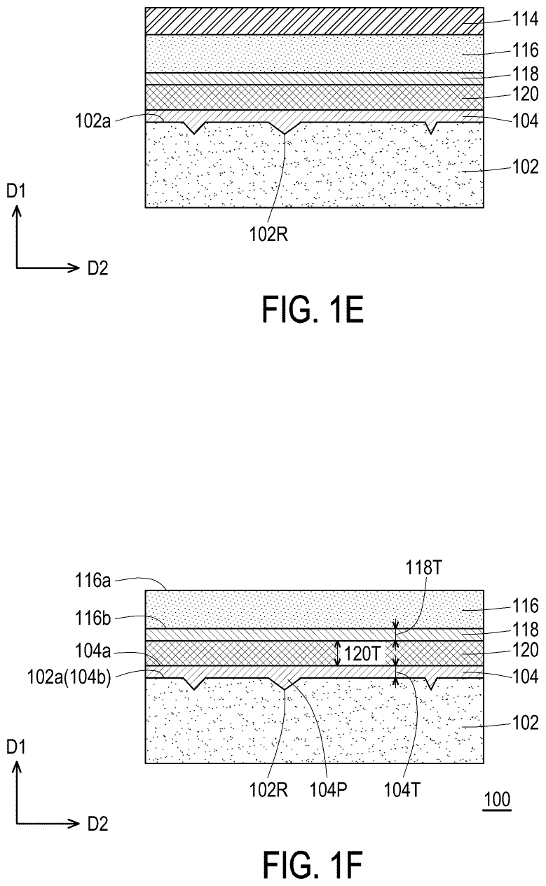

FIG. 1A to FIG. 1F are schematic cross-sectional views of various stages in a method of manufacturing a heat dissipation substrate of a semiconductor device according to some embodiments. It is noted that for clarity, the ratio of the thicknesses between the layers may not be the actual ratio. For example, the actual ratio of the thickness between the substrate (e.g., substrate 102) and each layer (e.g., first material layer 104, eutectic metal layer 120, second material layer 118 and bonding layer 116) thereon is larger than the ratio illustrated in drawings.

Referring to FIG. 1A, a substrate 102 is provided. The substrate 102 may have a thermal conductivity greater than that of silicon (about 1.56 W/cm*K). For example, the thermal conductivity of the substrate 102 is greater than 2.3 W/cm*K. The substrate 102 may include ceramic material, metal nitride, metal oxide, silicon carbide, graphene, diamond, the like or a combination thereof. The ceramic material may include silicon carbide (SiCx, 0.4<x<1.6), metal oxide such as aluminum oxide (AlOy, 0.4<y<2.6), metal nitride such as aluminum nitride (AlNz, 0.4<z<1.6), the like or a combination thereof. The metal nitride may further include boron nitride or the like. The metal oxide may further include yttrium oxide (Y₂O₃), yttrium aluminum garnet (YAG), aluminum oxide, beryllium oxide or the like. Diamond as used herein may refer to diamond or diamond like carbon (DLC) coating. The material of the substrate 102 may be amorphous, crystal or polycrystalline. For example, ceramic material includes amorphous ceramic material and/or polycrystalline ceramic material, silicon carbide includes crystal silicon carbide (SiC) and/or polycrystalline silicon carbide (SiC), and aluminum nitride includes crystal aluminum nitride (AlN) and/or polycrystalline aluminum nitride (AlN). The foregoing materials have thermal conductivity greater than that of silicon. For example, the thermal conductivity of ceramic is about 2.0 W/cm*K, the thermal conductivity of silicon carbide is about 3.6 W/cm*K, the thermal conductivity of aluminum nitride is about 3.2 W/cm*K, and the thermal conductivity of boron nitride is about 7.51 W/cm*K. The thermal conductivity of a diamond is about 6 W/cm*K or higher, for example, between about 15 W/cm*K and about 30 W/cm*K, and the thermal conductivity of the diamond like carbon coating is between about 4 W/cm*K and about 10 W/cm*K. The substrate 102 is also referred to as high thermal dissipation substrate. The substrate 102 may be formed by using a casting process, a deposition process such as chemical vapor deposition (CVD) process and liquid phase deposition (LPD) process, physical vapor transport process or the like. A thickness of the substrate 102 is in a range of 300 μm to 1000 μm, for example. A surface 102a (e.g., top surface) of the substrate 102 may be rough or uneven, which may be resulted from the manufacturing process (e.g., sintering process) of the substrate 102. A roughness of the surface 102a is larger than 1 nm, for example. In some embodiments, the substrate 102 has a plurality of recesses 102R, apertures or gaps at the surface 102a. The substrate 102 may be a ceramic substrate. However, the disclosure is not limited thereto. The substrate 102 may be any other suitable substrate.

Then, a first material layer 104 is formed on the surface 102a of the substrate 102 along a first direction D1, to form a first structure S1. The direction D1 is a vertical direction (e.g., z direction), and a direction D2 substantially perpendicular to the direction D1 is a horizontal direction (e.g., x direction or y direction), for example. The first material layer 104 may be formed by a deposition process such as physical vapor deposition (PVD) process and chemical vapor deposition (CVD) process, a sputtering process or the like. A thickness of the first material layer 104 is in a range of 1 nm to 10000 nm, for example. In some embodiments, the first material layer 104 includes a material having properties such that when the first material layer 104 is combined with a material of a second material layer 118 of FIG. 1B and heated to a predetermined temperature, a metal in a eutectic phase is formed. In alternative embodiments, the first material layer 104 may include other materials or elements that produce a eutectic metal combined with the material of a second material layer 118. In some embodiments, the first material layer 104 includes a first component of a eutectic metal, and the second material layer 118 includes a second component of the eutectic metal. When the first component and the second component of the eutectic metal are heated at the eutectic point for the eutectic metal, the first component and the second component react and liquefy or melt, and then return to a solid when the temperature is decreased, forming the eutectic metal. For example, the first component of the first material layer 104 is Ge, Si, Al, Au, Sn, In or Cu, and the second component of the second material layer 118 is Ge, Si, Al, Au or Cu. The eutectic metal includes AlGe, AuSi, AuIn, CuSn, AuSn, AuGe, AlSi or the like.

The first material layer 104 may be conformally formed on the substrate 102. For example, as shown in FIG. 1A, the recesses 102R of the substrate 102 are filled by the first material layer 104, and the first material layer 104 also has a plurality of recesses 104R corresponding to the recesses 102R, apertures or gaps of the substrate 102. In other words, the first material layer 104 has a rough surface 104a, 104b or uneven surface, and a roughness of the surface 104a, 104b is similar to that of the substrate 102. For example, the roughness of the surface 104a, 104b is larger than 1 nm. In some embodiments, the surface 104b is also the surface 102 of the substrate 102a, and the surface 104a is opposite to the surface 104b.

Referring to FIG. 1B, a substrate 112 is provided. In some embodiments, the substrate 112 is a silicon substrate, a glass substrate, or any suitable substrate which may provide a substantially flat (e.g., planar) surface for the following layers formed thereon. For example, the substrate 112 has a surface 112a (e.g., top surface), and the roughness of the surface 112a is smaller than 1 nm. The roughness of the surface 112a of the substrate 112 may be smaller than that of the surface 102a of the substrate 102. The substrate 112 is a silicon substrate, for example. The substrate 112 may be coated with at least one debond layer (not shown).

Then, an etch stop layer 114 and a bonding layer 116 may be formed on the substrate 112 along the first direction D1. For example, the etch stop layer 114 is formed on the substrate 112, and the bonding layer 116 is formed on the etch stop layer 114. A material of the etch stop layer 114 may have a different material than a material of the bonding layer 116. The material of the etch stop layer 114 may include a dielectric material such as silicon nitride, silicon oxide, silicon oxynitride, or the like, and the etch stop layer 114 may be formed by a deposition process such as atomic layer deposition (ALD) process, physical vapor deposition (PVD) process and chemical vapor deposition (CVD) process, spin-on coating process or the like. The material of the bonding layer 116 may include a silicon-containing dielectric material such as SiO, SiC, SiN, SiON, SiOC, SiCN and SiOCN, metal oxide such as aluminum oxide, metal nitride such as aluminum nitride or the like. However, the disclosure is not limited thereto. In alternative embodiments, other materials having adhesion properties may also be applicable as materials for the bonding layer 116. In some embodiments, the bonding layer 116 is formed by a deposition process such as atomic layer deposition (ALD) process, physical vapor deposition (PVD) process and chemical vapor deposition (CVD) process, spin-on coating process or the like.

In some embodiments, since the substrate 112 has a substantially flat surface 112a (e.g., surface 112a with low roughness), the etch stop layer 114 formed thereon also has a substantially flat surface 114a (e.g., surface 114a with low roughness). The surface 114a of the etch stop layer 114 is also a surface 116b of the bonding layer 116. In other words, the surface 116b of the bonding layer 116 has low roughness and is substantially flat, for example. In some embodiments, the surface 116b of the bonding layer 116 has a roughness smaller than 1 nm.

After that, a second material layer 118 is formed on a surface 116a opposite to the surface 116b of the bonding layer 116, to form a second structure S2. As mentioned above, a material of the second material layer 118 includes a second component of the eutectic metal. If the first material layer 104 includes Al and the second material layer 118 includes Ge, the combination of (Al+Ge) has a eutectic phase in a certain chemical composition and when heated to a certain temperature, at a eutectic point, the combination of (Al+Ge) reacts and melts or liquefies to form AlGe. Similarly, the combination of (Au+Si), (Au+In), (Cu+Sn), (Au+Sn), (Au+Ge) or (Al+Si) has a eutectic phase. The second material layer 118 may be formed by a deposition process such as physical vapor deposition (PVD) process and chemical vapor deposition (CVD) process, sputtering process or the like. A thickness of the second material layer 118 is in a range of 1 nm to 10000 nm, for example.

Referring to FIG. 1C and FIG. 1D, the first structure S1 and the second structure S2 are bonded. For example, as shown in FIG. 1C, the second structure S2 is inverted, i.e., rotated by about 180 degrees, from the view shown in FIG. 1B. Then, the first structure S1 and the second structure S2 are disposed in a face-to-face configuration and bonded together using a bonding process such as direct bonding process, by coupling a surface 104a of the first material layer 104 and a surface 118a of the second material layer 118. A shown in FIG. 1C, due to the recesses 104R at the surface 104a of the first material layer 104, voids 119, apertures or gaps may form between the second material layer 118 and the first material layer 104.

Then, as shown in FIG. 1D, a eutectic metal layer 120 is formed between the first substrate 102 and the second substrate 112. In some embodiments, by performing a heating process to the first structure S1 and the second structure S2 at a temperature that is at or above the eutectic point for the materials of the first material layer 104 and the second material layer 118. The heating process be a thermal compressing process, a thermal annealing process or other heating technique. The heating process includes heating the first structure S1 and the second structure S2 to a temperature of about 100° C. to 600° C. under a pressure of about 1 MPa to 100 MPa, for example. In an embodiment wherein the first material layer 104 includes Al and the second material layer 118 includes Ge, the heating process is performed at a temperature of about 425° C. The eutectic point of AlGe is about 419° C. at a composition of about 0.49 wt % Al/(Al+Ge), and thus heating the first structure S1 and the second structure S2 to this temperature causes Al from the first material layer 104 to react with Ge of the second material layer 118 and form AlGe in a liquid form, for example. When the heating process stops and the first structure S1 and the second structure S2 are cooled, the AlGe hardens and becomes a solid, forming a eutectic metal layer 120 shown in FIG. 1C including the eutectic metal (e.g., that includes the AlGe). However, the disclosure is not limited thereto. The heating process may be performed at any other suitable temperature and under any other suitable pressure according to the requirements. In alternative embodiments, the heating process is performed at a temperature lower than 350° C., to prevent the second component of the second material layer 118 diffusing into the bonding layer 116. In such embodiments, the eutectic metal may include AuIn, CuSn, AuSn or the like having the eutectic point lower than 350° C. For example, the eutectic point of AuIn is about 156° C. at a composition of about 0.6 wt % Au/(Au+In), the eutectic point of CuSn is about 231° C. at a composition of about 5 wt % Cu/(Cu+Sn), and the eutectic point of AuSn is about 280° C. at a composition of about 80 wt % Au/(Au+Sn).

When the first material layer 104 reacts with the second material layer 118 at the eutectic point, the resulting liquid eutectic metal layer 120 reflows and closes the voids 119, apertures or gaps formed between the first material layer 104 and the second material layer 118. At least a portion of the first material layer 104 and at least a portion of the second material layer 118 form the eutectic metal layer 120 when the temperature is lowered, and the eutectic metal layer 120 includes the materials of the first material layer 104 and the second material layer 118. The eutectic metal layer 120 closes the voids 119, apertures or gaps that previously were disposed between the second material layer 118 and on the surface (e.g., top surface) 104a of the first material layer 104. The resulting eutectic metal layer 120 includes a eutectic metal. In some embodiments, the eutectic metal layer 120 includes a eutectic metal including AlGe, AuSi, AuIn, CuSn, AuSn, AuGe, AlSi or the like. For example, the eutectic metal layer 120 includes a eutectic metal including AlGe or AuSi: Al or Au from the first material layer 104 combines with the Ge or Si from the second material layer 118 to form the AlGe or AuSi during the heating process.

Referring to FIG. 1E, the substrate 112 is removed. The substrate 112 may be removed through a laser transfer process, a thinning process such as CMP process, an etch process such as wet etch process and dry etch process or the like. During the removal of the substrate 112, the etch stop layer 114 functions as a stop layer, to prevent the removal process from damaging the bonding layer 116. In some embodiments, after the removal of the substrate 112, the etch stop layer 114 is entirely exposed.

Referring to FIG. 1F, after the substrate 112 is removed, the etch stop layer 114 is removed. The etch stop layer 114 may be removed through an etch process such as wet etch process and dry etch process or the like. In some embodiments, after the removal of the etch stop layer 114, a heat dissipation substrate 100 is formed. The heat dissipation substrate 100 is also referred to as thermal substrate, composite substate, combined substrate or the like. In some embodiments, through the above process described in FIG. 1A to FIG. 1F, the bonding layer 116 is transferred onto the substrate 102, and thus the method is also referred to as layer transfer process. By using the layer transfer process, there is no need to planarize the surface 102a of the substrate 102. It is noted that the layer transfer process may be applied to any substrate with or without a rough surface.

In some embodiments, the heat dissipation substrate 100 includes the substrate 102 and the first material layer 104, the eutectic metal layer 120, the second material layer 118 and the bonding layer 116 sequentially disposed on the substrate 102. For example, the first material layer 104 is disposed on the substrate 102, the eutectic metal layer 120 is disposed on the first material layer 104, the second material layer 118 is disposed on the eutectic metal layer 120, and the bonding layer 116 is disposed on the second material layer 118. The eutectic metal layer 120 is disposed between the substrate 102 and the bonding layer 118. For example, the eutectic metal layer 120 is disposed between the first material layer 104 and the second material layer 118. A thickness 120T of the eutectic metal layer 120 is, for example, greater than a thickness 104T, 118T of each of the first material layer 104 and the second material layer 118. However, the disclosure is not limited thereto. Sidewalls of the substrate 102, the first material layer 104, the eutectic metal layer 120, the second material layer 118 and the bonding layer 116 are substantially flush with one another, for example. The bonding layer 116 is the outermost layer of the heat dissipation substrate 100. In some embodiments, each of the substrate 102, the first material layer 104, the second material layer 118 and the eutectic metal layer 120 may provide heat dissipation.

In some embodiments, the substrate 102 has a rough surface 102a, and thus a surface 104b of the material layer 104 facing the substrate 102 is also a rough surface. For example, the substrate 102 includes a plurality of recesses 102R at the surface 102a, and the surface 104b of the first material layer 104 includes a plurality of protrusions 104P correspondingly disposed in the recesses 102R. The recesses 102R may be filled up by the protrusions 104P. In some embodiments, the protrusions 104P extend into the substrate 102 and disposed at an interface of the substrate 102 and the material layer 104. The roughness of the surface 104b may be similar to the roughness of the surface 102a. For example, the roughness of the surface 102a facing the eutectic metal layer 120 is larger than 1 nm, and the roughness of the surface 104b facing the substrate 102 is also larger than 1 nm. The first material layer 104 has a surface 104a opposite to the surface 104b, and the surface 104a faces the eutectic metal layer 120. The surface 104a may be substantially flat and has a roughness smaller than that of the surface 104b. For example, the roughness of the surface 104a of the first material layer 104 is smaller than 1 nm. In some embodiments, as shown in FIG. 1F, compared to the roughness of the surface 104a shown in FIG. 1A, the roughness of the surface 104a is reduced after performing the eutectic bonding process. In some embodiments, the bonding layer 116 has a surface 116b (e.g., inner surface) facing the eutectic metal layer 120 and a surface 116a (e.g., outer surface) opposite to the surface 116b. A roughness of the surface 116a of the bonding layer 116 is smaller than a roughness of the surface 102a of the substrate 102, for example.

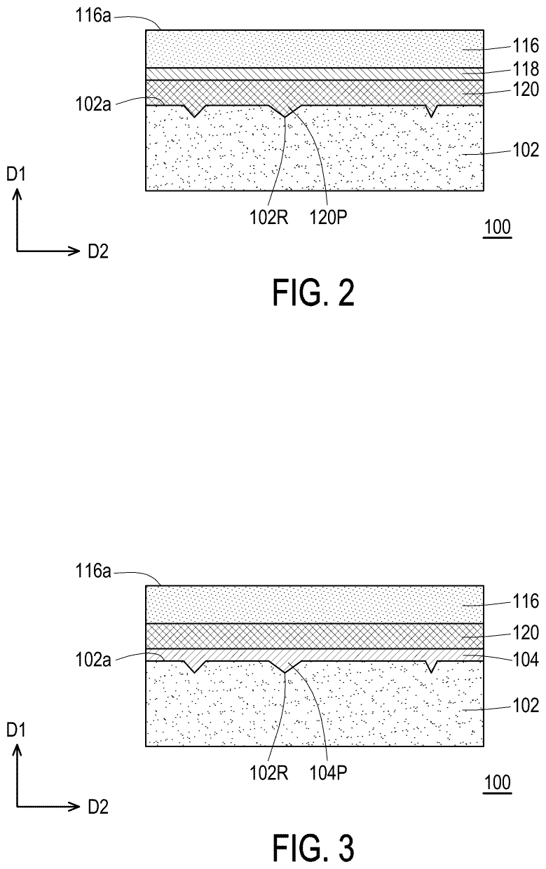

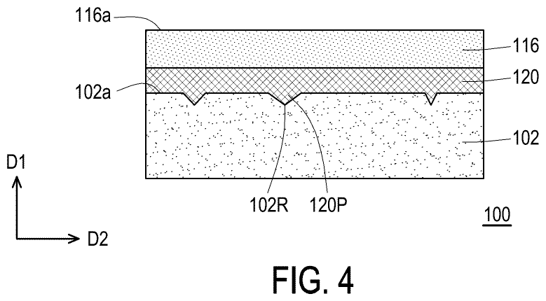

In some embodiments, as shown in FIG. 1D, after performing the eutectic bonding process, portions of the first material layer 104 and the second material layer 118 are remained without transforming into the eutectic metal layer 120, and thus the first material layer 104 and the second material layer 118 are remained in the heat dissipation substrate 100 of FIG. 1F. However, the disclose is not limited thereto. The first material layer 104 and the second material layer 118 may be partially or entirely transformed into the eutectic metal layer 120 depending on the requirements and/or the process conditions. That is, in alternative embodiments, at least one of the first material layer 104 and the second material layer 118 is not included in the formed heat dissipation substrate 100. For example, as shown in FIG. 2, the first material layer 104 is omitted, and thus the eutectic metal layer 120 is in direct contact with the substrate 102. The eutectic metal layer 120 may include protrusions 120P extending into the substrate 102. The protrusions 120P fill up the recesses 102R, and the protrusions 120P are disposed at an interface of the substrate 102 and the eutectic metal layer 120, for example. In an embodiment of FIG. 3, the second material layer 118 is omitted, and thus the eutectic metal layer 120 is in direct contact with the bonding layer 116. In an embodiment of FIG. 4, both first and second material layers 104 and 118 are omitted, and thus the eutectic metal layer 120 is in direct contact with the substrate 102 and the bonding layer 116. A roughness of the surface 116a of the bonding layer 116 is smaller than a roughness of the surface 102a of the substrate 102, for example.

In some embodiments, the substrate 102 may have a rough surface 102a, and the bonding layer 116 thereon may have a flat surface 116a. This is because the bonding layer 116 is pre-formed on another substrate and then transferred onto the substrate 102 through the eutectic bonding process instead of directly forming on the substrate 102. In some embodiments, through the layer transfer process including the eutectic bonding process, the substrate (e.g., ceramic substrate) 102 having thermal dissipation capacity and surface topography may be combined with the bonding layer 116 having a flat surface, to form the heat dissipation substrate 100. Thus, the heat dissipation substrate 100 may provide a flat surface (e.g., surface 116a) for bonding and provide heat dissipation and support for the components bonded thereto. Accordingly, the heat dissipation substrate is suitable for three-dimensional integrated circuit (3DIC) integration, high power device application, bond-and-etch-back semiconductor on isolation (BESOI) technique, smart-cut technique and the like.

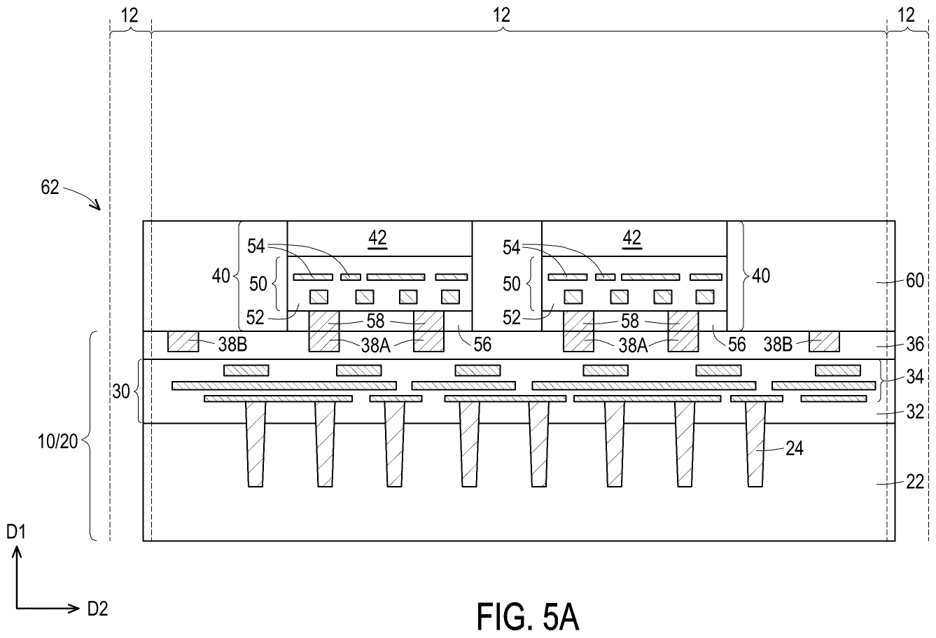

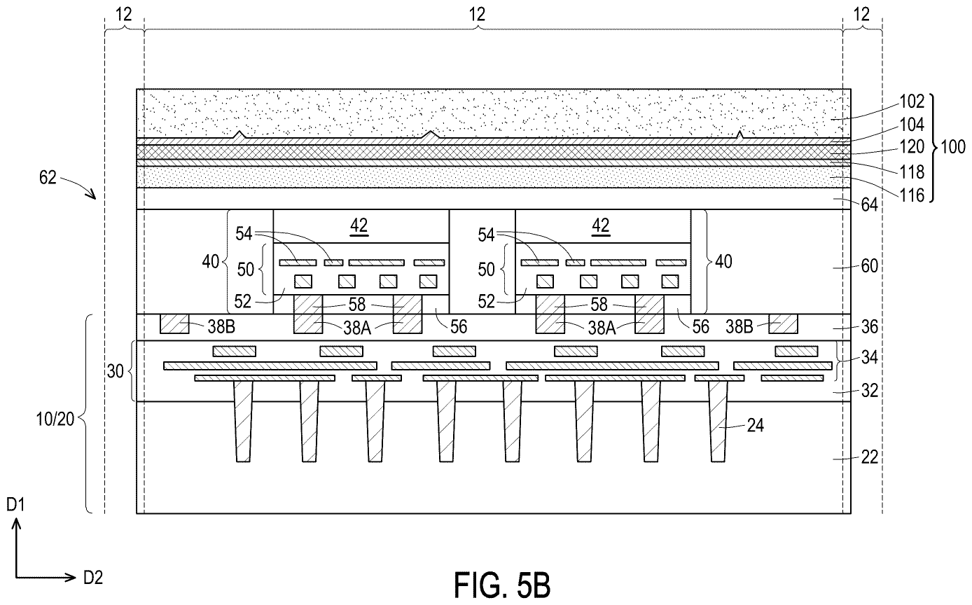

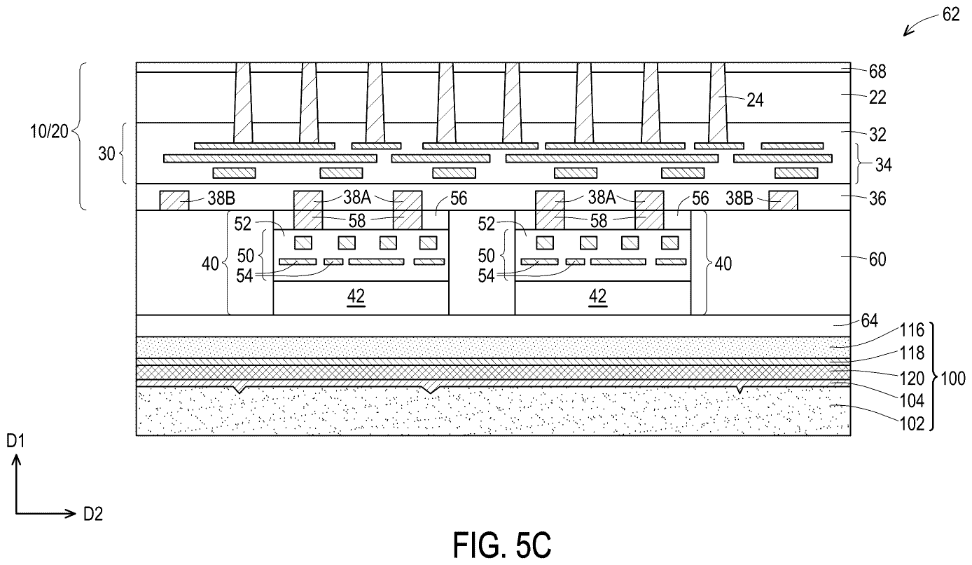

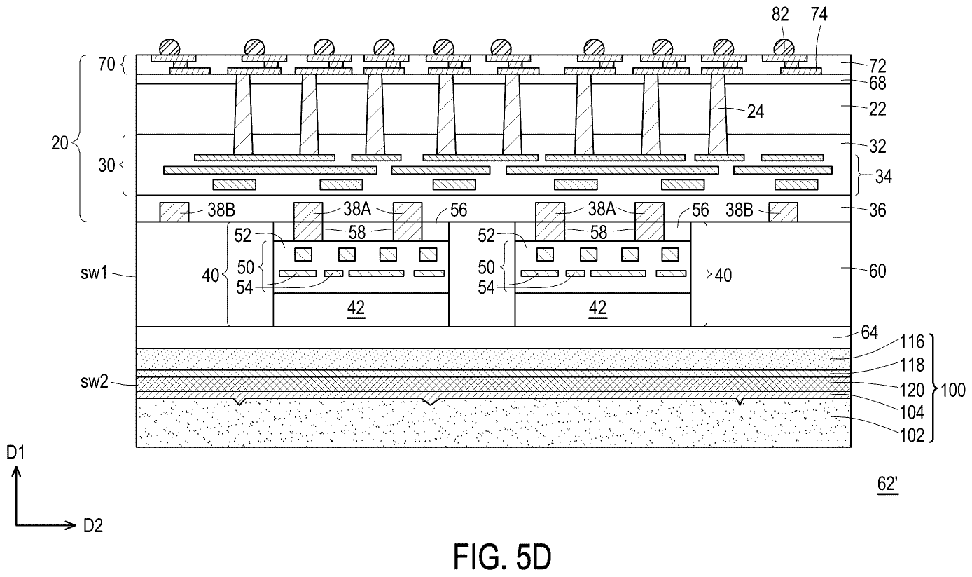

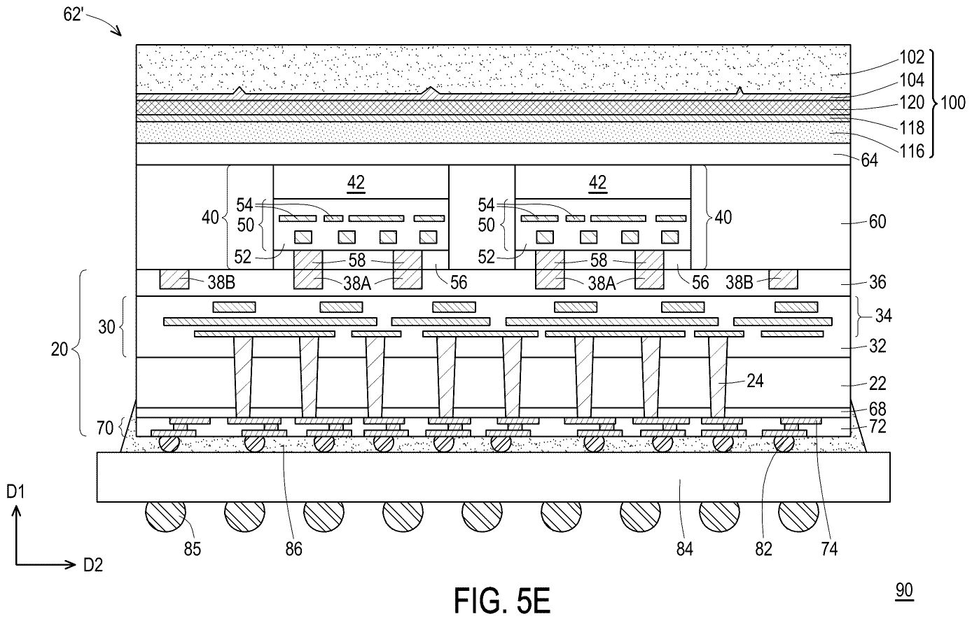

FIG. 5A to FIG. 5E are schematic cross-sectional views of various stages in a method of forming a semiconductor device according to some embodiments.

Referring to FIG. 5A, a package component 10 is provided. The package component 10 has a first surface (e.g., a front-side surface) and a second surface (e.g., a backside surface) opposite to the first surface. The package component 10 (also referred to as a bottom wafer) may include a plurality of die regions 12 that are singulated in subsequent steps to form a plurality of dies 20. For example, the die regions 12 are separated by scribe line regions (not shown) therebetween. In some embodiments, the dies 20 have the same size (e.g., same height and/or area). In alternative embodiments, the dies 20 have different sizes (e.g., different heights and/or areas). The dies 20 may be of the same type or different types. Each die 20 may be a logic die (e.g., central processing unit (CPU), graphics processing unit (GPU), system-on-chips (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or a combination thereof. The die 20 will be packaged in subsequent processing to form a package. A thickness of the die 20 along a direction D1 is in a range of 600 μm and 900 μm, for example. The direction D1 is a vertical direction (e.g., z direction), and a direction D2 substantially perpendicular to the direction D1 is a horizontal direction (e.g., x direction or y direction), for example. However, the disclosure is not limited thereto. The die 20 may have any suitable thickness. In some embodiments, the die 20 is also referred to as device die.

The die 20 may include a substrate 22 and an interconnect structure 30. The substrate 22 may be a semiconductor substrate such as substrate of silicon, doped or undoped, or an active layer of a semiconductor-on-insulator (SOI) substrate. The substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used. The substrate 22 has a first surface and a second surface opposite to the first surface. The first surface is an active surface and the second surface is a non-active surface, for example.

Integrated circuit devices (not shown) may be formed at the first surface (e.g., active surface) of the substrate 22. The integrated circuit devices may include transistors such as Complementary Metal-Oxide Semiconductor (CMOS) transistors, resistors, capacitors, diodes, and/or the like.

In some embodiments, the substrate 22 includes through vias 24. The through vias 24 are also referred to as through-silicon vias (TSVs) or through-semiconductor vias (also TSVs). The through vias 24 may be electrically connected to the integrated circuit devices. In some embodiments, the through vias 24 extend from the first surface of the substrate 22 (or a level higher than the first surface of the substrate 22 as shown in FIG. 5A) to an intermediate level of the substrate 22. The intermediate level of the substrate 22 is between the first surface and the second surface of the substrate 22. Each of the through vias 24 may be surrounded by a dielectric isolation layer (not shown), which is used for electrically insulating the corresponding through via 24 from the substrate 22.

The interconnect structure 30 is over the first surface of the substrate 22 and the integrated circuit device. The interconnect structure 30 may include an inter-layer dielectric (ILD) (not separately illustrated) filling the spaces between the gate stacks of transistors (not shown) in the integrated circuit devices. The ILD may include one or more dielectric layers formed of materials such as phospho-silicate glass (PSG), boro-silicate glass (BSG), boron-doped phospho-silicate glass (BPSG), undoped silicate glass (USG), or the like. The interconnect structure 30 may further include conductive plugs (not separately illustrated) in the ILD. The conductive plugs are used to electrically connect the integrated circuit devices to overlying conductive lines and vias. For example, when the integrated circuit devices are transistors, the conductive plugs electrically connect to the gates and the source and drain regions of the transistors. The conductive plugs may be formed of tungsten, cobalt, nickel, copper, silver, gold, aluminum, the like, or a combination thereof.

In some embodiments, the interconnect structure 30 include one or more dielectric layer(s) 32 and conductive features 34 in the dielectric layer(s) 32. The dielectric layer 32 may include a low-k dielectric material such as PSG, BSG, BPSG, USG, or the like. The dielectric layer 32 may further include an oxide such as silicon oxide or aluminum oxide; a nitride such as silicon nitride; a carbide such as silicon carbide; the like; or a combination thereof such as silicon oxynitride, silicon oxycarbide, silicon carbonitride, silicon oxycarbonitride or the like. Other dielectric material may also be used, such as polymer such as polybenzoxazole (PBO), polyimide, a benzocyclobuten (BCB) based polymer, or the like. The conductive features 34 may include conductive vias and/or conductive lines to interconnect the integrated circuit devices of the substrate 22. The conductive feature 34 may be formed of a conductive material, such as a metal, such as copper, cobalt, aluminum, gold, a combination thereof, or the like. Each conductive feature 34 may be formed in and/or on the dielectric layer 32. The interconnect structure 30 may be formed by a damascene process, such as a single damascene process, a dual damascene process, or the like.

In some embodiments, the die 20 further includes a bonding layer 36. The bonding layer 36 is formed over the interconnect structure 30. The bonding layer 36 may include silicon-containing dielectric material such as SiO, SiC, SiN, SiON, SiOC, SiCN, SiOCN, the like, or a combination thereof. The bonding layer 36 may be planarized using a CMP process or a mechanical grinding process so that its outmost surface (e.g., top surface) is planar.

Bonding pads 38A, 38B may be formed in the bonding layer 36. The bonding pads 38A, 38B may include copper, and may be formed through a damascene process. The bonding layer 36 and the bonding pads 38A, 38B may be planarized using a CMP process or a mechanical grinding process so that its outmost surface (e.g., top surface) is planar. The bonding pads 38A are electrically connected to the underlying conductive features 34 such as conductive lines and vias, the integrated circuit devices, and the through vias 24. The bonding pads 38A may be also referred to as active bonding pads since they are used for bonding to the overlaying top die, and are electrically connected to the conductive features 34 and possibly the through vias 24. The bonding pads 38B may be also referred to as dummy bonding pads since they are used for reducing pattern loading effect in the process such as CMP process. The bonding pads 38B may be electrically floating.

As shown in FIG. 5A, dies 40 (also referred to as top dies) are bonded to the dies 20 (also referred to as bottom dies) in the package component 10 along the direction D1, to form a package structure. In some embodiments, each of the dies 40 is a logic die such as a Central Processing Unit (CPU) die, a microcontroller (MCU) die, an input-output (IO) die, a BaseBand die, or the like. The dies 40 may also include memory dies. In some embodiments, the die 40 may generate more heat than the die 20. However, the disclosure is not limited thereto. A width of the die 40 along the direction D2 is smaller than a width of the die 20 along the direction D2, for example. The die 40 may have a similar structure to the die 20. For example, the die 40 includes a substrate 42, an interconnect structure 50, a bonding layer 56 and bonding pads 58. The substrate 42 may be a semiconductor substrate such as a substrate of silicon, doped or undoped, or an active layer of a semiconductor-on-insulator (SOI) substrate. The substrate 42 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used.

The interconnect structure 50 may be electrically connected to integrated circuit devices such as active devices and passive devices in the die 40. The interconnect structure 50 include one or more dielectric layer(s) 52 and conductive features 54 in the dielectric layer(s) 52. The dielectric layers 52 may include low-k dielectric materials such as PSG, BSG, BPSG, USG, or the like. The dielectric layers 52 may further include oxides such as silicon oxide or aluminum oxide; nitrides such as silicon nitride; carbides such as silicon carbide; the like; or a combination thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The conductive features 54 may include conductive vias and/or conductive lines to interconnect the integrated circuit devices of the substrate 42. The conductive features 54 may be formed of a conductive material, such as metal, including copper, cobalt, aluminum, gold, a combination thereof, or the like. Each conductive feature 54 may be formed in and/or on the dielectric layer 52. The interconnect structure 50 may be formed by a damascene process, such as single damascene process, dual damascene process, or the like.

The bonding layer 56 is formed over the interconnect structure 50. The bonding layer 56 may include silicon-containing dielectric material such as SiO, SiC, SiN, SiON, SiOC, SiCN, SiOCN, the like, or a combination thereof. The bonding pads 58 may be formed in the bonding layer 56. The bonding pads 58 are electrically connected to the underlying conductive features 54 such as conductive lines and vias and the integrated circuit devices and used for bonding to the overlaying bottom die. The bonding pads 58 may include copper, and may be formed through a damascene process. The bonding layer 56 and the bonding pads 58 may be planarized using a CMP process or a mechanical grinding process so that its surface is planar.

The dies 40 and the die 20 may be bonded through a hybrid bonding. For example, the bonding pads 58 are bonded to the bonding pads 38A through metal-to-metal direct bonding. The metal-to-metal direct bonding may include copper-to-copper direct bonding. Furthermore, the bonding layers 56 are bonded to the bonding layer 36 through fusion bonding, for example, with Si-O-Si bonds being generated. In some embodiments in which the package component 10 is a wafer, the bonding is also referred to as a chip on wafer bonding.

Then, an encapsulant 60 is formed over the die 20 to encapsulate the dies 40. In some embodiments, the encapsulant 60 fills the gap(s) between the dies 40. In some embodiments, the encapsulant 60 includes a dielectric material such as oxide (e.g., silicon oxide) or the like, and the encapsulant 60 is formed by a depositing process or a suitable process for gap filling. In alternative embodiments, the encapsulant 60 includes a molding compound or the like. The molding compound may include a base material and filler particles in the base material, the base material may include a polymer, a resin, and/or an epoxy, and the filler particles may include silica, aluminum oxide, silicon oxide and the like. In such embodiments, the encapsulant 60 is formed by dispensing a molding compound in a flowable form, and curing the molding compound as a solid. In some embodiments, a planarized process such as CMP is performed on the material of the encapsulant 60 until the dies 40 are exposed. Thus, a surface of the encapsulant 60 is substantially coplanar with surfaces of the dies 40, for example. In some embodiments, the bonded structure illustrated in FIG. 5A is also referred to as reconstructed component 62 or reconstructed wafer hereinafter.

Referring to FIG. 5B, a heat dissipation substrate 100 is bonded to the reconstructed component 62. The heat dissipation substrate 100 is the heat dissipation substrate 100 of FIG. 1F, FIG. 2 to FIG. 4 or the like. In some embodiments, before bonding the heat dissipation substrate 100, a bonding layer 64 is formed on the reconstructed component 62. The heat dissipation substrate 100 and the reconstructed component 62 are bonded through bonding the bonding layer 116 and the bonding layer 64. For example, the bonding layer 64 is formed on the surfaces of the dies 40 and the encapsulant 60. The bonding layer 64 may include silicon-containing dielectric material such as SiO, SiC, SiN, SiON, SiOC, SiCN and SiOCN, metal oxide such as aluminum oxide, metal nitride such as aluminum nitride or the like. In alternative embodiments, other materials having adhesion properties may also be applicable as materials for the bonding layer 64. The material of the bonding layer 64 may be the same as or different from the material of the bonding layer 116. In some embodiments, the bonding layer 64 is formed by suitable fabrication techniques, such as ALD, CVD, PECVD, spin-on coating or the like.

Referring to FIG. 5C, after bonding to the heat dissipation substrate 100, the structure shown in FIG. 5B may be turned upside down. Then, the substrate 22 of the die 20 is thinned, so as to expose the through vias 24, for example. In some embodiments, the substrate 22 is partially removed by a thinning process such as a CMP process or a mechanical grinding process. After performing the thinning process, the through vias 24 may be exposed. Then, the substrate 22 of the die 20 may be recessed to form recesses, and some portions (the illustrated top portions) of the through vias 24 protrude beyond the substrate 22. In some embodiments, as shown in FIG. 5C, a dielectric isolation layer 68 is then be formed. The formation of the dielectric isolation layer 68 may include a deposition process to deposit a dielectric layer into the recesses generated by recessing the substrate 22, so that the protruding portions of the through vias 24 are in the dielectric layer, followed by a planarization process. The portions of the dielectric layer beyond the through vias 24 are removed, and the remaining portions of the dielectric layer form the dielectric isolation layer 68, which becomes parts of dies 20 and the package component 10. After the thinning process, the thickness of the die 20 along the direction D1 is in a range of 50 μm and 100 μm, for example. In some embodiments, during the thinning process, the heat dissipation substrate 100 serves as a supporting substrate, and thus another carrier substrate is omitted.

Referring to FIG. 5D, a redistribution layer (RDL) structure 70 is formed on the dies 20 and 40 over the heat dissipation substrate 100. In some embodiments, the RDL structure 70 includes dielectric layers 72 and RDLs 74 in the dielectric layers 72. The RDL structure 70 may be formed by forming the dielectric layer 72, forming a plurality of openings in the dielectric layer 72 and forming the RDL 74 in the dielectric layer 72. The dielectric layer 72 may include an organic material such as PBO, polyimide, BCB or the like, an inorganic material such as silicon oxide, silicon nitride or the like. The RDL 74 may be formed by a damascene process, such as a single damascene process, a dual damascene process, or the like. In some embodiments, a dielectric layer 76 is formed over the RDL structure 70. In some embodiments, the dielectric layer 76 is similar to the dielectric layer 32, so the detailed description thereof is omitted herein.

Then, conductive connectors 82 are formed on the RDL structure 70 over the heat dissipation substrate 100. The conductive connectors 82 may include solder bumps, and/or may include metal pillars (e.g., copper pillars), solder caps formed on metal pillars, and/or the like. In some embodiments, the conductive connectors 82 are controlled collapse chip connection (C4) bumps. For example, portions of the outermost dielectric layer 72 are removed to form a plurality of the openings, and then the conductive connectors 82 are formed in the openings to electrically connect the RDL structure 70. A singulation process is optionally performed on the reconstructed component 62 by cutting along scribe line regions (e.g., dashed lines), e.g., around the die region 12, to form packages 60′ (e.g., semiconductor devices). The singulation process may include sawing, etching, dicing, the like, or a combination thereof. For example, the singulation process includes sawing the package component 10, the encapsulant 60 encapsulating the dies 40, the RDL structure 70 and the heat dissipation substrate 100. The singulation process singulates the die region 12 from adjacent regions to form a singulated package 62′ illustrated in FIG. 5D. The singulated package 62′ is from the die region 12.

The package 62′ may include the heat dissipation substrate 100, the dies 40 over the heat dissipation substrate 100, the die 20 bonded to the dies 40, the RDL structure 70 electrically connected to the die 20 and the conductive connectors 82 electrically connected to the RDL structure 70. In some embodiments, the bonding layer 64 is disposed between the encapsulant 60 and the heat dissipation substrate 100 and between the die 40 and the heat dissipation substrate 100. The encapsulant 60 encapsulates the dies 40, and a sidewall sw1 of the encapsulant 60 may be substantially flush with a sidewall sw2 of the heat dissipation substrate 100. For example, the sidewall sw1 of the encapsulant 60 is substantially flush with sidewalls of the substrate 102, the first material layer 104, the eutectic metal layer 120, the second material layer 118 and the bonding layer 116. The bonding layer 64 is in direct contact with the bonding layer 116, for example. In an embodiment in which the bonding layer 64 and the bonding layer 116 include the same material, an interface may be not observed or does not exist between the bonding layer 64 and the bonding layer 116. In such embodiment, the bonding layer 64 and the bonding layer 116 may be merged into a single layer. In some embodiments, the thermal conductivity of the heat dissipation substrate 100 is larger than the substrate (e.g., silicon substrate) 22, 42 of the die 20, 40. In some embodiments, the heat dissipation substrate 100 serves as a supporting substrate, and thus the process for formation of the package 62′ such as thinning process and the formation of the RDL are performed on the heat dissipation substrate 100. However, the disclosure is not limited thereto. In alternative embodiments, the reconstructed component 62 of FIG. 1A may be bonded to a carrier substrate, and the thinning process and the formation of the RDL are performed on the reconstructed component 62 over the carrier substrate. After that, the resulted structure is bonded to the heat dissipation substrate 100 and removed from the carrier substrate. In such embodiments, only the formation of the conductive connectors 82 may be performed over the heat dissipation substrate 100.

Referring to FIG. 5E, the package 62′ is bonded to a package component 84. In some embodiments, the package component 84 is an interconnect substrate such as a package substrate, an interposer, another package or a printed circuit board. The package component 84 has conductive connectors 85. The conductive connectors 85 may include solder bumps, and/or may include metal pillars (e.g., copper pillars), solder caps formed on metal pillars, and/or the like. In some embodiments, an underfill 86 is formed around the conductive connectors 82 between the package 62′ and the package component 84. A package 90 is thus formed. The package 90 may include the package 62′ and the package component 84 electrically connected to the package 62′ through the conductive connectors 82.

In some embodiments, the thermal conductivity of the heat dissipation substrate 100 is larger than the silicon substrate, and thus the heat dissipation substrate 100 may replace the silicon substrate in 3DIC applications, to improve the heat dissipation capacity. In some embodiments, the heat dissipation substrate 100 is integrated into the package 62′ such as System-on-Integrated-Chip (SoIC). As such, heat generated during the operation of the package 62′ or 90 may be sufficiently and efficiently dissipated by the heat dissipation substrate 100. With the integration of the heat dissipation substrate 100, the performance and the lifetime of the package 62′ or 90 may be improved.

The heat dissipation substrate 100 may be also applied in any suitable semiconductor device.

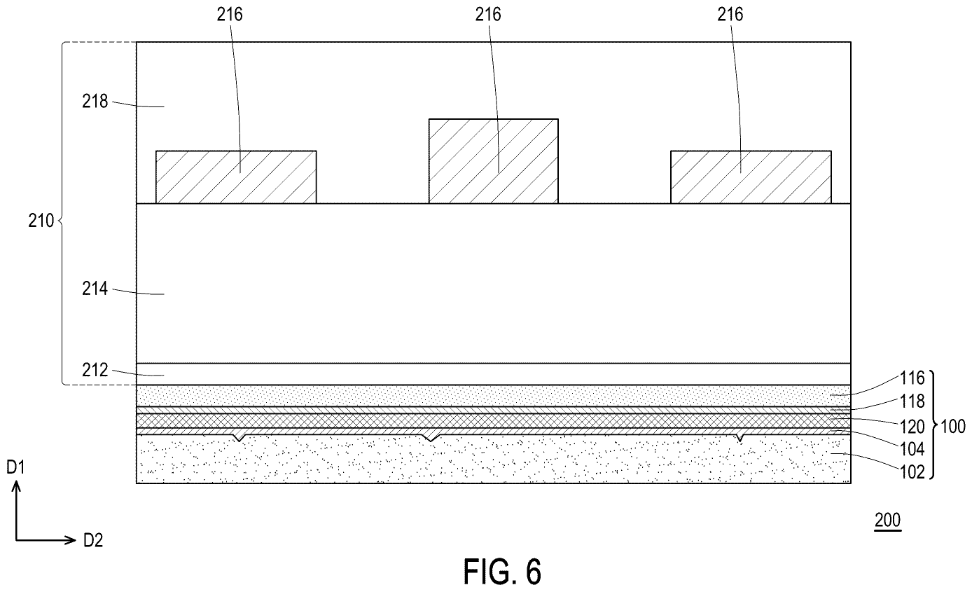

FIG. 6 is a schematic cross-sectional view of a semiconductor device according to some embodiments.

Referring to FIG. 6, a semiconductor device 200 includes a heat dissipation substrate 100 and a device 210 bonded to the heat dissipation substrate 100 along a first direction D1, to form a first structure S1. The direction D1 is a vertical direction (e.g., z direction), and a direction D2 substantially perpendicular to the direction D1 is a horizontal direction (e.g., x direction or y direction), for example. The device 210 may be a high power device such as a GaN-based high power device and/or a high heat generating device which may generate heat during operation. In some embodiments, the device 210 includes a bonding layer 212, a multilayer 214 such as a GaN-based multilayer on the bonding layer 212, a plurality of conductive contacts 216 electrically connected to the multilayer 214 and a passivation layer 218 covering the conductive contacts 216. The device 210 is bonded to the heat dissipation substrate 100 through the bonding layer 212 and the bonding layer 116. The bonding layer 212 is in direct contact with the bonding layer 116, for example. The bonding layer 212 is similar to the bonding layer 64 as mentioned above, so the detailed description thereof is omitted herein. The multilayer 214 may include a plurality of GaN-based layers (e.g., GaN layer and AlGaN layer) stacked on one another along the first direction D1. The conductive contacts 216 may include a gate contact and a source contact and a drain contact at opposite sides of the gate contact along the second direction D2. In some embodiments, by bonding the heat dissipation substrate 100 to the device 210, the heat generated during the operation of the device 210 may be sufficiently and efficiently dissipated by the heat dissipation substrate 100. With the integration of the heat dissipation substrate 100, the performance and the lifetime of the device 210 may be improved.

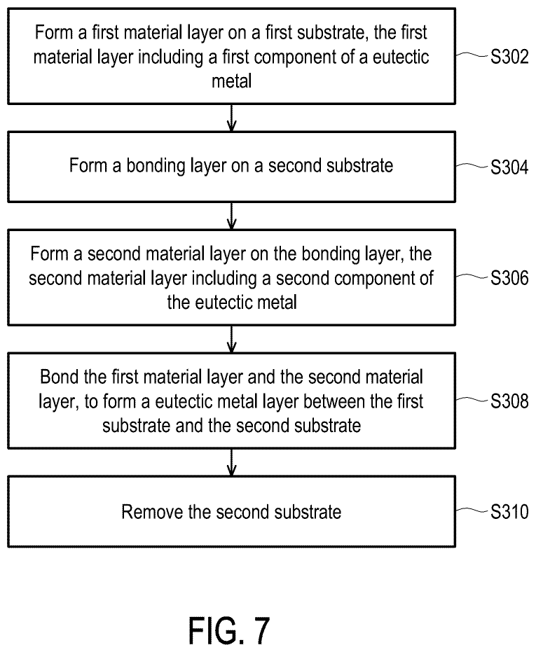

FIG. 7 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S302, a first material layer is formed on a first substrate, the first material layer comprising a first component of a eutectic metal. FIG. 1A illustrates a varying view corresponding to some embodiments of act S302.

At act S304, a bonding layer is formed on a second substrate. FIG. 1A illustrates a varying view corresponding to some embodiments of act S304.

At act S306, a second material layer is formed on the bonding layer, and the second material layer includes a second component of the eutectic metal. FIG. 1B illustrates a varying view corresponding to some embodiments of act S306.

At act S308, the first material layer and the second material layer are bonded, to form a eutectic metal layer between the first substrate and the second substrate. FIG. 1C and FIG. 1D illustrate varying views corresponding to some embodiments of act S308.

At act S310, the second substrate is removed. FIG. 1E and FIG. 1F illustrate varying views corresponding to some embodiments of act S310.

According to some embodiments of the disclosure, a semiconductor device includes a heat dissipation substrate. The heat dissipation substrate includes a substrate, a first material layer, a second material layer, a eutectic metal layer and a bonding layer. The first material layer is disposed on the first substrate and includes a first component of a eutectic metal. The second material layer is disposed on the first material layer and includes a second component of the eutectic metal. The eutectic metal layer is disposed between the first material layer and the second material layer and includes the eutectic metal. The bonding layer is disposed on the second material layer.

According to some embodiments of the disclosure, a semiconductor device includes a heat dissipation substrate and at least one die. The heat dissipation substrate includes a substrate, a eutectic metal layer and a bonding layer. The eutectic metal layer includes a eutectic metal. The eutectic metal layer is disposed between the substrate and the bonding layer. The at least one die is bonded to the heat dissipation substrate through the bonding layer.

According to some embodiments of the disclosure, a method of forming a semiconductor device includes following steps. A first material layer is formed on a first substrate, and the first material layer includes a first component of a eutectic metal. A bonding layer is formed on a second substrate. A second material layer is formed on the bonding layer, and the second material layer includes a second component of the eutectic metal. A second material layer is formed on the bonding layer, and the second material layer includes a second component of the eutectic metal. The first material layer and the second material layer are bonded, to form a eutectic metal layer between the first substrate and the second substrate. The second substrate is removed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a heat dissipation substrate, comprising:
a substrate;
a first material layer on the first substrate and comprising a first component of a eutectic metal;
a second material layer on the first material layer and comprising a second component of the eutectic metal;
a eutectic metal layer between the first material layer and the second material layer and comprising the eutectic metal; and
a bonding layer on the second material layer.

2. The semiconductor device of claim 1, wherein the first material layer comprises a plurality of protrusions disposed in the substrate.

3. The semiconductor device of claim 1, wherein the first material layer has a first surface facing the eutectic metal layer and a second surface facing the substrate, and a roughness of the first surface is smaller than a roughness of the second surface.

4. The semiconductor device of claim 1, wherein a material of the substrate comprises ceramic, SiC, AlN, diamond and a combination thereof.

5. The semiconductor device of claim 1, wherein the eutectic metal comprises AuIn, CuSn, AuSn, AuGe, AuSi, AlGe or AlSi.

6. The semiconductor device of claim 1, wherein a thickness of the eutectic metal layer is greater than a thickness of each of the first material layer and the second material layer.

7. A semiconductor device, comprising:
a heat dissipation substrate, comprising:
a substrate;
a eutectic metal layer, comprising a eutectic metal; and
a bonding layer, wherein the eutectic metal layer is disposed between the substrate and the bonding layer; and
at least one die, wherein the at least one die is bonded to the heat dissipation substrate through the bonding layer.

8. The semiconductor device of claim 7, further comprising a first material layer, wherein the first material layer comprises a first component of the eutectic metal and is disposed between the substrate and the eutectic metal layer.

9. The semiconductor device of claim 7, further comprising a second material layer, wherein the second material layer comprises a second component of the eutectic metal and is disposed between the eutectic metal layer and the bonding layer.

10. The semiconductor device of claim 7, wherein the eutectic metal comprises AuIn, CuSn, AuSn, AuGe, AuSi, AlGe or AlSi.

11. The semiconductor device of claim 7, further comprising an interconnect substrate, wherein the at least one die is electrically bonded to the interconnect substrate and disposed between the interconnect substrate and the heat dissipation substrate.

12. The semiconductor device of claim 11, further comprising an encapsulant encapsulating the at least one die, wherein a sidewall of the encapsulant is substantially flush with a sidewall of the heat dissipation substrate.

13. The semiconductor device of claim 7, wherein the substrate has a thermal conductivity greater than silicon.

14. The semiconductor device of claim 7, wherein the substrate has a surface facing the eutectic metal layer, the bonding layer has a first surface facing the eutectic metal layer and a second surface opposite to the first surface, and a roughness of the second surface of the bonding layer is smaller than a roughness of the surface of the substrate.

15. The semiconductor device of claim 7, wherein the bonding layer is in direct contact with the at least one die.

16. A method of forming a semiconductor device, comprising:
forming a first material layer on a first substrate, the first material layer comprising a first component of a eutectic metal;
forming a bonding layer on a second substrate;
forming a second material layer on the bonding layer, the second material layer comprising a second component of the eutectic metal;
bonding the first material layer and the second material layer, to form a eutectic metal layer between the first substrate and the second substrate; and
removing the second substrate.

17. The method of claim 16, further comprising forming an etch stop layer between the second substrate and the bonding layer.

18. The method of claim 17, further comprising removing the etch stop layer after removing the second substrate.

19. The method of claim 16, further comprising performing a planarization process on the bonding layer after removing the second substrate.

20. The method of claim 16, wherein a plurality of recesses of the first substrate are filled by the first material layer.
